(19) United States
(12) Patent Application Publication
(10) Pub. No.: US 2025/0349556 A1
(43) Pub. Date: Nov. 13, 2025

(54) Package and Manufacturing Method

(71) Applicant: AT&S Austria Technologie & Systemtechnik Aktiengesellschaft, Leoben (AT)

(72) Inventor: Jeesoo MOK, Leoben (AT)

(21) Appl. No.: 18/873,855

(22) PCT Filed: Jun. 7, 2023
(86) PCT No.: PCT/EP2023/065293

§ 371 Date: Dec. 11, 2024

(30) Foreign Application Priority Data
Jun. 15, 2022 (CN) 202210679111.4

(51) Int. Cl. H01L 21/48; H01L 23/498

(52) U.S. Cl. CPC H01L 21/4846; H01L 21/486; H01L 23/498; H01L 23/49827

(57) ABSTRACT

A package and its manufacturing method are presented. The package includes a core having at least one through hole delimited by a wall surface which is at least partially covered with at least one electrically conductive plating material, a first layer stack on one main surface of the core, and a second layer stack on an opposing other main surface of the core. The first layer stack has electrically conductive elements with a higher integration density than further electrically conductive elements with a lower integration density of the second layer stack. The further electrically conductive elements include at least one cylindrical vertical electrically conductive connection element for contributing to the formation of an electrically conductive connection interface at a main surface of the second layer stack facing away from the core.

### CROSS REFERENCE TO RELATED APPLICATIONS

This application is a national stage application, filed under 35 U.S.C. § 371, of International Patent Application No. PCT/EP2023/065293, filed on Jun. 7, 2023, claiming priority of patent application Ser. No. 20/221,0679111.4 filed on Jun. 15, 2022, in China, the disclosures of these patent applications being incorporated by reference herein in their entirety.

### TECHNICAL FIELD

The disclosure relates to a package and to a method of manufacturing a package.

### TECHNOLOGICAL BACKGROUND

In the context of growing product functionalities of component carriers equipped with one or more components and increasing miniaturization of such components as well as a rising number of components to be connected to the component carriers such as printed circuit boards, increasingly more powerful array-like components or packages having several components are being employed, which have a plurality of contacts or connections, with ever smaller spacing between these contacts. In particular, component carriers shall be mechanically robust and electrically reliable so as to be operable even under harsh conditions.

Conventional approaches of forming component carrier-type packages are still challenging.

### SUMMARY

There may be a need to form a compact and reliable component carrier-type package.

According to an exemplary embodiment of the disclosure, a package is provided which comprises a core having at least one through hole delimited by a wall surface which is at least partially covered with at least one electrically conductive plating material (or plating structure), a first layer stack on one main surface of the core, and a second layer stack on an opposing other main surface of the core, wherein the first layer stack has electrically conductive elements with a higher integration density than further electrically conductive elements with a lower integration density of the second layer stack, and wherein the further electrically conductive elements comprise at least one cylindrical vertical electrically conductive connection element for contributing to the formation of an electrically conductive connection interface at a main surface of the second layer stack facing away from the core.

According to another exemplary embodiment of the disclosure, a method of manufacturing a package is provided, wherein the method comprises providing a core having at least one through hole delimited by a wall surface which is at least partially covered with at least one electrically conductive plating material, forming a first layer stack on one main surface of the core, forming a second layer stack on an opposing other main surface of the core, wherein the first layer stack has electrically conductive elements with a higher integration density than further electrically conductive elements with a lower integration density of the second layer stack, and providing the further electrically conductive elements with at least one cylindrical vertical electrically conductive connection element for contributing to the formation of an electrically conductive connection interface at a main surface of the second layer stack facing away from the core.

In the context of the present application, the term “package” may particularly denote any support structure which is capable of accommodating one or more components thereon and/or therein for providing mechanical support and/or electrical connectivity. In other words, a package may be configured as a mechanical and/or electronic carrier for components. In particular, a package may be a component carrier-type device. Such a component carrier may be one of a printed circuit board, an organic interposer, and an IC (integrated circuit) substrate. A component carrier may also be a hybrid board combining different types of component carriers.

In the context of the present application, the term “core” may particularly denote a central carrier structure of the package. For example, the core may comprise fully cured dielectric material, such as FR4. However, the core may also comprise glass, a ceramic, a semiconductor such as silicon, and/or a metal.

In the context of the present application, the term “through hole” may particularly denote a vertical or slanted hole extending through the entire thickness of the core.

In the context of the present application, the term “plating material” may particularly denote electrically conductive material which can be formed by one or more plating processes. For instance, the plating material can be an electrically conductive plating coating covering said wall surface partially or entirely. It is also possible that the plating material fills the through hole only partially while leaving a central void or dielectric volume. In another embodiment, the plating material fills the entire through hole. One or more plating processes by which the plating material may be formed may comprise electroless plating (for example sputtering or electroless plating by a chemical process) and/or electroplating (in particular galvanic plating).

In the context of the present application, the term “stack” may particularly denote an arrangement of multiple planar layer structures which are mounted in parallel on top of one another. Layer structures may particularly denote a continuous layer, a patterned layer or a plurality of non-consecutive islands within a common plane.

In the context of the present application, the term “integration density” may denote a number of electrically conductive elements (in particular trace elements (such as wiring structures), connection elements (such as pads) and/or vertical through connections (such as metallic vias)) per area or volume of the respective layer stack. Hence, the amount of electrically conductive elements in a higher density layer stack may be higher than the amount of electrically conductive elements in a lower density layer stack. Thus, integration density may mean a quantity of electrically conductive elements per area or volume. The integration density in a lower density layer stack can be less than in a higher density layer stack. Correspondingly, the line space ratio and/or line pitch may be higher in a lower density layer stack than in a higher density layer stack. The term “line space ratio” may denote a pair of characteristic dimensions of an electrically conductive trace element, i.e., a characteristic line width of one electrically conductive trace element and a characteristic distance between adjacent electrically conductive trace elements. The term “line pitch” may denote the distance between corresponding edges of two adjacent electrically conductive elements.

In the context of the present application, the term “cylindrical vertical electrically conductive connection element” may particularly denote one or more vertically extending metallic structures, for example comprising or consisting of copper. The term “vertical” may denote a thickness direction of the second layer stack. Examples for a cylindrical vertical electrically conductive connection element may be a metal pillar (in particular a copper pillar), a metal cylinder, or a metal-filled drill hole (such as a plated mechanically drilled via). In one embodiment, all electrically conductive elements of the second layer stack may be vertical through connections. However, in an embodiment, the second layer stack may additionally comprise one or more horizontal electrical connection elements. A corresponding horizontal electrical connection element may be located at a surface of the second layer stack and/or in an interior thereof.

According to an exemplary embodiment of the disclosure, a package is provided which comprises a core with one or more plated through holes. The core may be sandwiched between a first layer stack with a higher integration density of electrically conductive elements and a second layer stack with a lower integration density of further electrically conductive elements. The latter may have one or more cylindrical vertical electrically conductive connection elements (for example circular cylindrical pillars or columns) which may contribute to the creation of an exterior electrically conductive connection interface of the package. At said exterior connection interface, the package may be mounted on a mounting base (for example a component carrier such as a printed circuit board). At an opposing exterior connection interface of the package, one or more components (for instance a semiconductor die) may be mounted. Hence, the package may function as redistribution structure for providing a transition between smaller characteristic dimensions on the component side and larger characteristic dimensions on the side for connection with a mounting base. The transition between larger dimensions (which are for instance typical for printed circuit board technology) and smaller dimensions (which may be typical for semiconductor technology) can be accomplished in a highly compact way so that signal and/or electric energy transmission may be performed in a vertical direction along short connection paths and thus with small losses. At the same time, the described package may be manufactured in a simple and efficient way. More specifically, the manufacturing effort may be reasonably low, since high-density integration can be provided only where functionally needed. Advantageously, undesired phenomena such as warpage may be efficiently suppressed in the package due to the compensation which may be achieved by the combination of a high-density stack and a low-density stack to mitigate the warpage. Thus, a reliable package may be provided.

### Overview of Embodiments

In the following, further exemplary embodiments of the package and the method will be explained.

The core or any of the layer stacks may have a sheet (or plate) like design comprising two opposing main surfaces. The main surfaces may form the two largest surface areas of the core or layer stack. The main surfaces are connected by circumferential side walls. The thickness of a core or any of the layer stacks is defined by the distance between the two opposing main surfaces. The main surfaces may comprise functional sections, such as conductive traces or conductive interconnections with further elements.

In an embodiment, at least part of the electrically conductive elements is electrically coupled with the at least one plating material. Preferably, said electrically conductive elements can be electrically coupled to a portion of the plating material which is located at a periphery of the core, in particular at a top side thereof.

In an embodiment, at least part of the further electrically conductive elements is electrically coupled with the at least one plating material. Preferably, said further electrically conductive elements can be electrically coupled to a portion of the plating material which is located at a periphery of the core, in particular at a bottom side thereof.

In an embodiment, the package comprises at least one electrically conductive planar connection pad at least partially covering a respective one of the at least one through hole at one of the one main surface and the other main surface of the core and being electrically connected with a respective one of the at least one plating material. Correspondingly, the package may comprise at least one further electrically conductive planar connection pad at least partially covering a respective one of the at least one through hole at the other one of the main surface and the other main surface of the core and being electrically connected with a respective one of the at least one plating material. For instance, a respective cylindrical vertical electrically conductive connection element may have a tubular shape closed on a bottom side by a first planar connection pad (which may be circular) and closed on a top side by a second planar connection pad (which may be circular as well). A respective electrically conductive planar connection pad may cover a respective through hole entirely or only partially. In particular, there may be a lateral shift between a center of the pad and a center of the through hole so that the through hole will not be covered completely by the pad. Moreover, a respective further electrically conductive planar connection pad may cover a respective through hole entirely or only partially. In particular, there may be a lateral shift between a center of the further pad and a center of the through hole so that the through hole will not be covered completely by the further pad. To put it shortly, a plating structure of the core may be not exactly located in the center of the respective connection pad but may be a bit shifted. Alternatively, a respective pad may be in alignment with an assigned through hole.

In an embodiment, at least one of the at least one electrically conductive planar connection pad and the at least one further electrically conductive planar connection pad extends circumferentially beyond the respective one of the at least one plating material (which may also be denoted as plating structure). In other words, a diameter of a respective pad may be larger than a diameter of the through hole. This may ensure a sufficient alignment between pad and through hole even in the presence of manufacturing tolerances. Consequently, a package with high electric reliability may be manufactured.

In an embodiment, vertical through connections of the electrically conductive elements are directly electrically connected with one of the at least one electrically conductive planar connection pad and the at least one further electrically conductive planar connection pad. For instance, such vertical through connections may comprise metal pillars, metal-filled laser vias, metal-filled mechanically drilled vias, stacked vias and/or pads, etc. Such vertical through connections of any of the layer stacks may be directly, i.e. without one or more other electrically conductive elements in between, connected with the connection pads of the core. This may ensure short electrically conductive paths in the vertical direction and may thus reduce ohmic losses and consequently parasitic heating, as well as signal loss.

In an embodiment, the at least one cylindrical vertical electrically conductive connection element is directly electrically connected with one of the at least one electrically conductive planar connection pad and the at least one further electrically conductive planar connection pad. In such an embodiment, no additional electrically conductive elements are arranged between connection pad and cylindrical vertical electrically conductive connection element. This may render connection paths in z-direction short on the bottom side of the core. This may, in turn, contribute to high signal quality and a compact design.

In an embodiment, dielectric material of the first layer stack has a lower coefficient of thermal expansion (CTE) than dielectric material of the second layer stack. To control the warpage of the package, the first layer stack may be provided with lower CTE and the second layer stack may be provided with higher CTE. This design may reduce warpage so that even an asymmetric package according to an exemplary embodiment may behave in a similar way as a symmetric structure in terms of warpage due to the compensation of CTE mismatch of two stacks. Hence, the taken measure may allow to improve warpage control (see also the lines in FIG. 1 above and below a symmetry plane and indicating the phenomenon of warpage).

In an embodiment, an amount of dielectric material of the first layer stack is substantially the same as an amount of dielectric material of the second layer stack. For example, the amount of dielectric material of the layer stacks may differ by not more than ±10%, preferably by not more than ±5%. In particular, a sum of the thicknesses of the dielectric layers of the first layer stack may be substantially or exactly the same as a sum of the thicknesses of the dielectric layers of the second layer stack. It has turned out that this design rule significantly suppresses warpage and the tendency of delamination of the package due to the compensation of thickness and amount of the dielectric material for the two stacks.

In an embodiment, dielectric material of the first layer stack comprises or consists of a high Young modulus material. Descriptively speaking, the higher the value of the Young modulus, the stiffer is the corresponding dielectric material. In the context of the first layer stack, a high Young modulus material may have a value of the Young modulus above 10 MPa (in particular for Ajinomoto Build-up Film (ABF) material), in particular above 15 MPa (in particular for prepreg), or even above 25 MPa (in particular for core material).

In an embodiment, dielectric material of the second layer stack comprises or consists of a low Young modulus material. To put it shortly, the smaller the value of the Young modulus, the softer is the corresponding dielectric material. In the context of the second layer stack, a low Young modulus material may have a value of the Young modulus below 5 MPa. In particular, a low Young modulus material may have a value of the Young modulus in a range from 0.5 MPa to 0.7 MPa (in particular for Ajinomoto Build-up Film (ABF) material). Furthermore, a low Young modulus material may have a value of the Young modulus below 10 MPa (in particular for prepreg). It is also possible that a low Young modulus material may have a value of the Young modulus below 20 MPa (in particular for core material).

When the dielectric material of the first layer stack has a higher value of the Young modulus compared with the dielectric material of the second layer stack, highly advantageous properties in terms of suppressed warpage may be achieved.

More specifically, the two key parameters for warpage control of the package have turned out to be the CTE values and the values of the Young modulus of the dielectric materials of the first layer stack and the second layer stack. A particularly preferred combination in terms of warpage suppression is a first layer stack having dielectric material with a higher value of the Young modulus and a smaller CTE value than dielectric material of the second layer stack, which could compensate the CTE of two stacks with asymmetric structure.

However, while the value of the Young modulus may be higher for the first layer stack than for the second layer stack, it may also be vice versa, in particular when the CTE characteristics are adjusted accordingly.

In an embodiment, a respective one of the at least one plating material is electrically connected to and axially displaced with respect to an assigned one of the at least one cylindrical vertical electrically conductive connection element. The design of the package is compatible with tolerances between central axes of a through hole with plating material on the one hand and an assigned cylindrical vertical electrically conductive connection element on the other hand. This compatibility may be achieved in particular by sufficiently large connection pads in between.

In an embodiment, an integration density of the core with its at least one plating material is substantially the same as the integration density of the second layer stack with its further electrically conductive elements. Thus, the first layer stack may have the highest integration density among the three main constituents of the package, i.e., core and layer stacks. In contrast to this, both the core and the second layer stack may be manufactured with a lower integration density and thus in a simple way. The described design may combine compatibility with small pitches of semiconductor technology with a simple manufacturing process.

In an embodiment, an aspect ratio, i.e., a ratio between a height and a diameter of the at least one cylindrical vertical electrically conductive connection element, is at least 0.5, in particular is at least 1, for example at least 2. Hence, metal pillars or other cylindrical structures with high aspect ratio may be implemented for bridging sufficiently large spaces in vertical direction.

In an embodiment, a vertical thickness of the core is at least 500 μm, in particular at least 1 mm. Advantageously, a core with the mentioned high thickness may provide sufficient mechanical stability to avoid warpage even in the event of an asymmetric build up, i.e. when a layer sequence of the first layer stack differs significantly from a layer sequence of the second layer stack.

In an embodiment, the first layer stack comprises a redistribution structure, such as a redistribution layer (RDL), or a fanout-structure. A redistribution structure may function as an electric interface between large electrically conductive structures of the first layer stack, as characteristic for component carrier-technology, and smaller electrically conductive structures of a surface mounted component on the first layer stack, as characteristic for semiconductor technology. In particular, such a redistribution structure may taper from an interior of the package towards an exterior main surface of the first laminated layer stack (see for instance FIG. 1).

In an embodiment, the electrically conductive connection interface provides a grid array interface. In particular, said grid array interface may be a ball grid array interface or a land grid array interface. Land Grid Array (LGA) and Ball Grid Gray (BGA) are both Surface Mount Technologies (SMT), in particular for printed circuit boards or motherboards. They basically define how the package will actually be mounted, in particular on a PCB or a motherboard's socket. Essentially, the most basic difference between the two is that an LGA based package can be plugged in and out of the PCB or motherboard and can also be replaced. A BGA based package, however, may be soldered on the PCB or motherboard and thus cannot be plugged out or replaced. A Ball Grid Array, on the other hand, may have spherical contacts which are then soldered onto the PCB or motherboard. An LGA type package may be placed on top of a socket on a PCB or motherboard. In this context, the package may have flat surface contacts, whereas the PCB or motherboard socket may have pins.

In an embodiment, the at least one cylindrical vertical electrically conductive connection element is vertically spaced with respect to the electrically conductive connection interface by at least one further vertical electrically conductive connection element. For instance, the at least one further vertical electrically conductive connection element comprises at least one metal-filled via, in particular tapering away from the electrically conductive connection interface. Such an embodiment is shown, for example, in FIG. 1 and allows to manufacture the package with cylindrical vertical electrically conductive connection elements having a relatively small aspect ratio.

In another embodiment, the at least one cylindrical vertical electrically conductive connection element extends up to the electrically conductive connection interface. Hence, a single integral cylindrical vertical electrically conductive connection element may extend over the entire thickness of the second layer stack (see for example FIG. 2). With such cylindrical vertical electrically conductive connection elements having a sufficiently high aspect ratio, a very simple construction of the second layer stack may be achieved.

In an embodiment, the package comprises at least one component, in particular at least one semiconductor chip, being surface mounted on the first layer stack. In the context of the present application, the term “component” may particularly denote a device or member, for instance fulfilling an electronic and/or a thermal task. For instance, the component may be an electronic component. Such an electronic component may be an active component such as a semiconductor chip comprising a semiconductor material, in particular as a primary or basic material. The semiconductor material may for instance be a type IV semiconductor such as silicon or germanium, or may be a type III-V semiconductor material such as gallium arsenide. In particular, the semiconductor component may be a semiconductor chip such as a naked die or a molded die. At least one integrated circuit element may be monolithically integrated in such a semiconductor chip.

In an embodiment, the package comprises a mounting base, such as a component carrier, in particular a printed circuit board (PCB) or integrated circuit (IC) substrate, on which the second layer stack is mounted. Such a component carrier may form a mounting base for mounting the package forming, in turn, the basis for at least one surface mounted component.

In an embodiment, the package comprises a dielectric filling medium, in particular ink, at least partially filling a void volume of the at least one through hole between different sections of the plating material. In one embodiment, such a filling medium may be a dielectric ink or glue inserted into the void volume. By filling such a void volume or gap, void spaces within the readily manufactured package may be prevented which may improve the mechanical integrity and thus reliability of the package. Furthermore, such a filling medium may stabilize the plating material in the through hole of the core and may thereby promote a correct alignment of the various constituents of the package. However, the filling medium can also be a magnetic paste material. Such a material may reduce the inductance, which may be advantageous for decreasing the electromagnetic interference (EMI). For example, the magnetic paste may be filled in the hole by a plug in process.

In an embodiment, the at least one cylindrical vertical electrically conductive connection element comprises at least one metal pillar, in particular at least one copper pillar. Such a metal cylinder may be a prefabricated piece or inlay which may also be provided with large aspect ratio.

In an embodiment, the core comprises at least one of an organic core, glass, a ceramic, and a semiconductor, in particular silicon, or a metal. An organic core may comprise a dielectric material having an organic compound. In particular, dielectric material of the organic core may be made exclusively or at least substantially exclusively from organic material. In another embodiment, the organic core may comprise organic dielectric material and additionally another dielectric material. An organic compound may be a chemical compound that contains carbon-hydrogen bonds. For example, the organic core may comprise an organic resin material, an epoxy material, etc. In particular, printed circuit board (PCB) dielectrics or integrated circuit (IC) substrates dielectrics may be dielectrics used for the organic core. Alternatively, the core may be embodied as inorganic core, i.e. may comprise or consist of inorganic material. In particular, dielectric material of the inorganic core or even the entire inorganic core may be made exclusively or at least substantially exclusively from inorganic material. In another embodiment, the inorganic core may comprise inorganic dielectric material and additionally another dielectric material. An inorganic compound may be a chemical compound that lacks carbon-hydrogen bonds or a chemical compound that is not an organic compound. Examples of inorganic core materials are glass (in particular silica-based glass), a ceramic (such as aluminum nitride and/or aluminum oxide), and a material comprising a semiconductor (such as silicon oxide or silicon).

In an embodiment, the core has at least two through holes extending parallel to each other and each being delimited by a respective wall surface which is at least partially covered with a respective electrically conductive plating material. Correspondingly, the further electrically conductive elements may comprise at least two cylindrical vertical electrically conductive connection elements extending parallel to each other and each contributing to the provision of the electrically conductive connection interface. Arranging a plurality of parallel through holes in the core allows to increase the number of signals to be transmitted at the same time through the package. Each through hole filled at least partially with plating material may be connected with an assigned cylindrical vertical electrically conductive connection element for accomplishing said parallel signal transmission. Hence, a pattern according to which the through holed are formed in the core may correspond to a pattern according to which the cylindrical vertical electrically conductive connection elements are formed in the second layer stack.

In an embodiment, a respective stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, a respective stack is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier or a respective stack is configured as a printed circuit board, a substrate (in particular an IC substrate), or an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular coated with supra-conductive material or conductive polymers, such as graphene or poly (3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as component.

In an embodiment, a respective stack or the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples of nickel-free materials are ISIG (Immersion Silver Immersion Gold), and EPAG (Electroless Palladium Autocatalytic Gold).

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1 illustrates a cross-sectional view of a package according to an exemplary embodiment of the disclosure.

FIG. 2 illustrates a cross-sectional view of a package according to another exemplary embodiment of the disclosure.

FIG. 3, FIG. 4, FIG. 5, and FIG. 6 illustrate cross-sectional views of structures obtained during carrying out a method of manufacturing a package, shown in FIG. 6, according to an exemplary embodiment of the disclosure.

FIG. 7, FIG. 8, and FIG. 9 illustrate cross-sectional views of structures obtained during carrying out a method of manufacturing a package, shown in FIG. 9, according to an exemplary embodiment of the disclosure.

FIG. 10, FIG. 11, FIG. 12, FIG. 13, FIG. 14, and FIG. 15 illustrate cross-sectional views of structures obtained during carrying out a method of manufacturing a package, shown in FIG. 15, according to an exemplary embodiment of the disclosure.

FIG. 16, FIG. 17, and FIG. 18 illustrate cross-sectional views of structures obtained during carrying out a method of manufacturing a package, shown in FIG. 18, according to an exemplary embodiment of the disclosure.

FIG. 19 illustrates a cross-sectional view of a package according to another exemplary embodiment of the disclosure.

FIG. 20 illustrates a horizontal connection plane of the package according to FIG. 19.

FIG. 21 illustrates a cross-sectional view of a package according to still another exemplary embodiment of the disclosure.

### DETAILED DESCRIPTION OF THE ILLUSTRATED EMBODIMENTS

The illustrations in the drawings are schematically presented. In different drawings, similar or identical elements are provided with the same reference signs.

Before referring to the drawings, exemplary embodiments will be described in further detail, some basic considerations will be summarized based on which exemplary embodiments of the disclosure have been developed.

According to an exemplary embodiment of the disclosure, a package is provided with a central thick and therefore robust core traversed by preferably a plurality of parallel extending partially plated through holes. On one side of the core a first layer stack with high integration density redistribution structure is connected for carrying at least one surface mounted electronic component (preferably at least one semiconductor chip). On the other side of the core a second layer stack with smaller integration density is arranged having cylindrical vertical electrically conductive connection elements preferably aligned with and connected to the partially plated through holes of the core. A mounting base, such as a PCB, may carry the second layer stack. By such a package design, electric signals and/or electric energy may be transmitted along short paths in vertical (and, in certain embodiments, also in horizontal) direction between surface mounted component and mounting base. Hereby, the higher density first layer stack may function as a redistribution layer. Advantageously, the package design can be manufactured with low effort since a high integration region needs to be present only where absolutely needed, i.e., in the first layer stack. As a result, a simple, compact and reliable package may be provided.

In a preferred embodiment, the package is configured as asymmetric chip-last fan-out substrate. Due to the mechanically robust central core, the first layer stack and the second layer stack may have a mutually asymmetric design without the risk of excessive warpage. Due to the described construction of the package, one or more electronic components may be surface mounted at the very end of the manufacturing process, thereby increasing the yield and productivity. A redistribution structure integrated in the first layer stack may lead to a high-density fan-out design. The core may be embodied as a thick metallized through hole body, wherein copper pillars may constitute an interface (for instance a ball grid array interface) to a mounting base. On the other side of the core, a fine redistribution layer may be provided by the first layer stack. This design may allow for a proper warpage management of the package.

Exemplary applications of exemplary embodiments of the disclosure relate to fan-out substrates for server applications, data center applications, 5G applications, and related electronic devices.

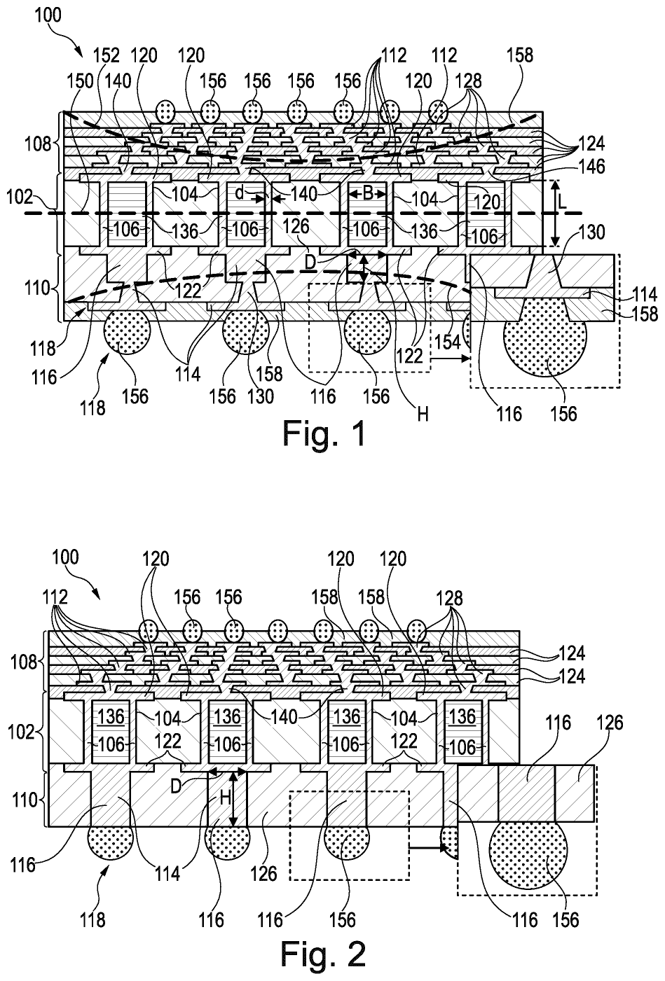

FIG. 1 illustrates a cross-sectional view of a package 100 according to an exemplary embodiment of the disclosure.

The illustrated package 100 comprises a central core 102, which may have dielectric material made for instance of FR4, silicon, glass, a ceramic, or may have a metal. Vertical through holes 104 are formed to extend in vertical direction and parallel to each other through the entire thickness of the core 102. As shown, the dielectric body of the core 102 can be provided with a large thickness, L, of for instance at least 500 μm, preferably larger than 1000 μm. This may ensure a high mechanical stability of the core 102 and of the package 100 as a whole.

As shown as well in FIG. 1, each through hole 104 is delimited by a cylindrical wall surface of core 102 which is covered with electrically conductive plating material 106, such as copper. More specifically, the entire wall surface delimiting a respective through hole 104 may be lined or coated continuously with a copper film having a thickness, d, for example in a range from 10 μm to 50 μm, for instance 25 μm. The plating material 106 may comprise a seed layer formed by electroless deposition (for example by sputtering or a chemical process) and a main layer on the seed layer formed by electroplating (such as galvanic plating). The plating material 106 is formed for vertically conducting electric power and/or electric signals. As can be taken from FIG. 1 as well, package 100 comprises a dielectric (or a magnetic) filling medium 136 which completely fills a void volume of each through hole 104. Said void volume may be defined as a volume inside the circumferential coating of plating material 106. For instance, said dielectric (or magnetic) filling medium 136 may be an electrically insulating ink, resin and/or glue. Descriptively speaking, the dielectric filling medium 136 fills up empty spaces within the tubular or hollow cylindrical plating structure in form of plating material 106 in each through hole 104. This dielectric filling avoids empty spaces in the interior of the package 100 and thereby increases the mechanical and thermal reliability, as well as the electric performance. A horizontal diameter, B, of the dielectric filling medium 136 may be in the range from 50 μm to 500 μm, for example 150 μm. As shown, an electric connection between a top side and a bottom side of the core 102 may be established exclusively by the vertical tubular plating material 106 of the through holes 104, and therefore in a very simple way.

Again referring to FIG. 1, electrically conductive planar connection pads 120 are provided, each covering an assigned one of the through holes 104 and being connected to an assigned plating material 106 at the upper main surface of the core 102. Consequently, each electrically conductive planar connection pad 120 is electrically connected with the plating material 106 corresponding to the assigned through hole 104.

Each of the electrically conductive planar connection pads 120 may have a circular shape or a rectangular shape (in particular a square shape). Correspondingly, further electrically conductive planar connection pads 122 are provided each covering an assigned one of the through holes 104 and being connected to an assigned plating material 106 at the lower main surface of the core 102. Consequently, each further electrically conductive planar connection pad 122 is electrically connected as well with the plating material 106 corresponding to the assigned through hole 104. Each of the further electrically conductive planar connection pads 122 may have a circular shape. In the cross-sectional view of FIG. 1, each plating material 106 with connected electrically conductive planar connection pad 120 and with connected further electrically conductive planar connection pad 122 may be shaped as rectangle with four horizontal extensions. Preferably, each set of through hole 104 with plating material 106, connected electrically conductive planar connection pad 120 and connected further electrically conductive planar connection pad 122 may be in axial alignment with each other in lateral direction. However, it may happen due to tolerances during the manufacturing process that vertical symmetry axes of a set of a through hole 104 with plating material 106, a connected electrically conductive planar connection pad 120 and a connected further electrically conductive planar connection pad 122 are slightly displaced with respect to each other. In order to compensate such potential tolerances which may occur during the manufacturing process, it is also possible that an electrically conductive planar connection pad 120 and/or a further electrically conductive planar connection pad 122 extends circumferentially, i.e., in a horizontal plane according to FIG. 1, beyond the assigned plating material 106 and through hole 104.

Furthermore, the package 100 comprises a first layer stack 108 on the upper main surface of the core 102. Moreover, a second layer stack 110 may be arranged on the lower main surface of the core 102. More specifically, each of the first layer stack 108 and the second layer stack 110 may be configured as laminated layer stack composed of electrically conductive layer structures (see reference signs 112, 128, 140 for the first layer stack 108 and reference signs 114, 116, 130 for the second layer stack 110) and one or more electrically insulating layer structures (see reference sign 124 for the first layer stack 108 and reference sign 126 for the second layer stack 110). As shown, the electrically conductive layer structures may comprise patterned or continuous copper layers and vertical through connections, for example copper pillars and/or copper filled laser vias which may be created by plating. The one or more electrically insulating layer structures may comprise a respective resin (such as a respective epoxy resin), preferably comprising reinforcing particles therein (for instance glass fibers or glass spheres). For instance, the electrically insulating layer structures may be made of prepreg or FR4. For example, each of the first layer stack 108 and the second layer stack 110 may be constructed as a printed circuit board (or a piece of a PCB) or an integrated circuit (IC) substrate.

As shown in FIG. 1, the first layer stack 108 has electrically conductive elements 112 with a higher integration density than further electrically conductive elements 114 with a lower integration density of the second layer stack 110. In particular, a number of electrically conductive elements 112 of the first layer stack 108 per volume is larger than a number of further electrically conductive elements 114 per volume in the second layer stack 110. When serving as an interposer between a mounting base 134 and at least one component 132 (see FIG. 18), a higher integration density of package 100 is functionally only required in the first layer stack 108 of the package 100 to comply with small pitches of one or more components (for instance semiconductor chips, see reference sign 132 in FIG. 18) to be surface mounted on the first layer stack 108. In contrast to this, since the second layer stack 110 is to be mounted on a mounting base (for instance a printed circuit board, see reference sign 134 in FIG. 18) with larger pitches, the higher manufacturing effort involved with the formation of high integration density regions may be omitted in the second layer stack 110. Thus, the entire manufacturing effort may be reduced by forming the more sophisticated high density integration region only in the first layer stack 108, but not in the second layer stack 110. As a consequence, an asymmetric build up with respect to a central axis 150 of package 100 is formed by the first layer stack 108 and the second layer stack 110 on opposing main surfaces of core 102. However, in view of the high thickness, L, of the core 102 and the resulting high robustness, a pronounced tendency of warpage (as indicated schematically by reference signs 152, 154) may nevertheless be avoided. Moreover, the design of the Young modulus and the coefficient of thermal expansion of the dielectric material of the first layer stack 108 and the second layer stack 110, as described below, may also contribute to a strong suppressing of warpage in package 100. Since an integration density of the core 102 with its plating material 106 in through holes 104 and its electrically conductive planar connection pads 120, 122 is substantially the same as the integration density of the further electrically conductive elements 114 of the second layer stack 110, the manufacturing effort may be further reduced also what concerns core 102. This simple construction of core 102 is also compatible with the functional requirements of package 100, since the integration density in core 102 may be already in compliance with the pitches in mounting base 134 (see FIG. 18).

Now referring specifically to the first layer stack 108, electrically conductive elements 112 in a lower part of first layer stack 108 are electrically coupled with the plating material 106 in each through hole 104. More specifically, vertical through connections 140 of the electrically conductive elements 112 at a bottom of the first layer stack 108 are directly electrically connected with the above-described electrically conductive planar connection pads 120. Furthermore, as shown in FIG. 1, the arrangement of the electrically conductive elements 112 tapers towards an upper main surface of the first layer stack 108 and therefore also tapers towards an upper main surface of package 100. In view of this design, the first layer stack 108 forms a redistribution structure 128 with a larger pitch at a lower main surface of the first layer stack 108 and a smaller pitch at an upper main surface of the first layer stack 108.

More specifically, the uppermost of the electrically conductive elements 112 may be provided with electrically conductive connection structures 156. For instance, the electrically conductive connection structures 156 may be solder balls, so that a solder connection can be established between the first layer stack 108 and surface mounted components (see reference sign 132 in FIG. 18). A patterned solder resist 158 may be formed on an upper surface of the first layer stack 108 of the package 100, so that the electrically conductive connection structures 156 can be formed selectively in openings of solder resist 158.

Now referring specifically to the second layer stack 110, a part of the further electrically conductive elements 114 in an upper portion of the second layer stack 110 is electrically coupled with the plating material 106 in the through holes 104. More specifically, the further electrically conductive elements 114 comprise a plurality of parallel cylindrical vertical electrically conductive connection elements 116 contributing to the formation of an electrically conductive connection interface 118 at a lower main surface of the second layer stack 110. In FIG. 1, the cylindrical vertical electrically conductive connection elements 116 are embodied as copper pillars. Said lower main surface faces away from the core 102 and faces a mounting base 134 when connected to the mounting base 134. As shown as well in FIG. 1, each of the cylindrical vertical electrically conductive connection elements 116 is directly electrically connected with a respective one of further electrically conductive planar connection pads 122. Preferably, the cylindrical vertical electrically conductive connection elements 116 are axially aligned with the further electrically conductive planar connection pads 122 and with the plating material 106 in the through holes 104. However, tolerances during the manufacturing process may also lead to a geometry in which each respective plating material 106 in a respective through hole 104 is electrically connected but axially displaced with respect to an assigned cylindrical vertical electrically conductive connection element 116. Such a misalignment may be compensated by the further electrically conductive planar connection pads 122 extending laterally beyond each through hole 104, preferably around the entire circumference of the through hole 104.

Furthermore, a ratio between a height H and a diameter D of each cylindrical vertical electrically conductive connection element 116 may be in a range from 0.5 to 1. To put it shortly, the cylindrical vertical electrically conductive connection elements 116 may be provided with a relatively high aspect ratio so as to extend over a significant vertical portion of the second layer stack 110. As shown, the second layer stack 110 provides a ball grid array (BGA) interface 118 at its exposed lower main surface. Here, a plurality of solder balls or the like may be provided as electrically conductive connection structures 156. A mounting base 134, such as a printed circuit board, may be connected to a lower main surface of the package 100 of FIG. 1 using the bottom-sided electrically conductive connection structures 156 (see FIG. 18). A patterned solder resist 158 may be formed on a lower surface of the second layer stack 110 of the package 100, so that the electrically conductive connection structures 156 can be formed in openings of solder resist 158.

However, according to FIG. 1, the cylindrical vertical electrically conductive connection elements 116 do not extend completely up to the grid array interface 118. In contrast to this, each of the cylindrical vertical electrically conductive connection elements 116 is vertically spaced with respect to the electrically conductive connection interface 118 by a respective one of further vertical electrically conductive connection elements 130. Said further vertical electrically conductive connection elements 130 are here embodied as laser-drilled metal-filled vias which taper away from the electrically conductive connection interface 118.

In the following, the dielectric properties of the first layer stack 108 and the second layer stack 110 will be described in further detail. Preferably, dielectric material 124 of the first layer stack 108 may have a lower coefficient of thermal expansion (CTE) than dielectric material 126 of the second layer stack 110. For example, the higher CTE value may be above and the lower CTE value may be below a CTE value of 45 ppm/K. Furthermore, dielectric material 124 of the first layer stack 108 may have a higher value of the Young modulus than dielectric material 126 of the second layer stack 110. For example, the higher value of the Young modulus may be above and the lower value of the Young modulus may be below a value of the Young modulus of 10 MPa. Advantageously, it has turned out that this design of CTE values in combination with Young modulus values in layer stacks 108, 110 may lead to a strong suppression of warpage despite of the asymmetric buildup of layer stacks 108, 110. For an appropriate warpage design it may further be advantageous to make sure that an amount of dielectric material 124 of the first layer stack 108 is substantially the same as an amount of dielectric material 126 of the second layer stack 110.

Still referring to FIG. 1, a mutual distance between adjacent electrically conductive layer structures is smaller in the first layer stack 108 compared to the second layer stack 110. Consequently, the higher integration density in said first layer stack 108 may correspond to the small line pitch of a connection surface of an electronic component 132 which may be surface mounted on the first layer stack 108 (see FIG. 18). Furthermore, the lower integration density in said second layer stack 110 may correspond to the larger line pitch of a connection surface of a mounting base 134 (such as a printed circuit board or another component carrier) which may be connected to a bottom surface of the second layer stack 110 (see FIG. 18). Thus, the redistribution structure 128 may translate or form an interface between the smaller dimensions of semiconductor technology and the larger dimensions of component carrier technology.

The described design of package 100 has advantages: Firstly, the fact that exclusively the plated material 106 in the through holes 104 and the electrically conductive planar connection pads 120, 122 accomplish the electric connection between the top side and the bottom side of the core 102 allows to design the core 102 with a very simple construction. Furthermore, this design may create extremely short electric paths in z-direction. This may lead to small signal loss and therefore high signal quality of electric signals propagating through the core 102. In addition, this may result in small heat dissipation inside of the package 100 due to the small ohmic losses. Consequently, thermal stress inside of package 100 may be low, which may advantageously avoid undesired phenomena such as delamination. Moreover, the large vertical thickness, L, of the core 102 may provide reliable mechanical support for the other constituents of the package 100. Hence, although an asymmetric build-up is formed on both opposing main surfaces of the core 102 according to FIG. 1, package 100 is not prone to warpage due to the high mechanical stability of the core 102. A further advantage is that in particular the core 102 and the second layer stack 110 may have a very simple construction. By adjusting the CTE values and Young modulus values of the dielectric material of the first and the second layer stacks 108, 110, warpage can be properly controlled.

FIG. 2 illustrates a cross-sectional view of a package 100 according to another exemplary embodiment of the disclosure.

The embodiment of FIG. 2 differs from the embodiment of FIG. 1 in particular in that, according to FIG. 2, each of the cylindrical vertical electrically conductive connection elements 116 extends directly up to the electrically conductive connection interface 118. Thus, cylindrical vertical electrically conductive connection elements 116 with even higher aspect ratio, for instance larger than one, can be implemented according to FIG. 2. For example, the cylindrical vertical electrically conductive connection elements 116 may be copper pillars. Due to the oblong cylindrical vertical electrically conductive connection elements 116 of FIG. 2, the further vertical electrically conductive connection elements 130 of FIG. 1 can be omitted in FIG. 2. This further simplifies the manufacture of the package 100 according to FIG. 2.

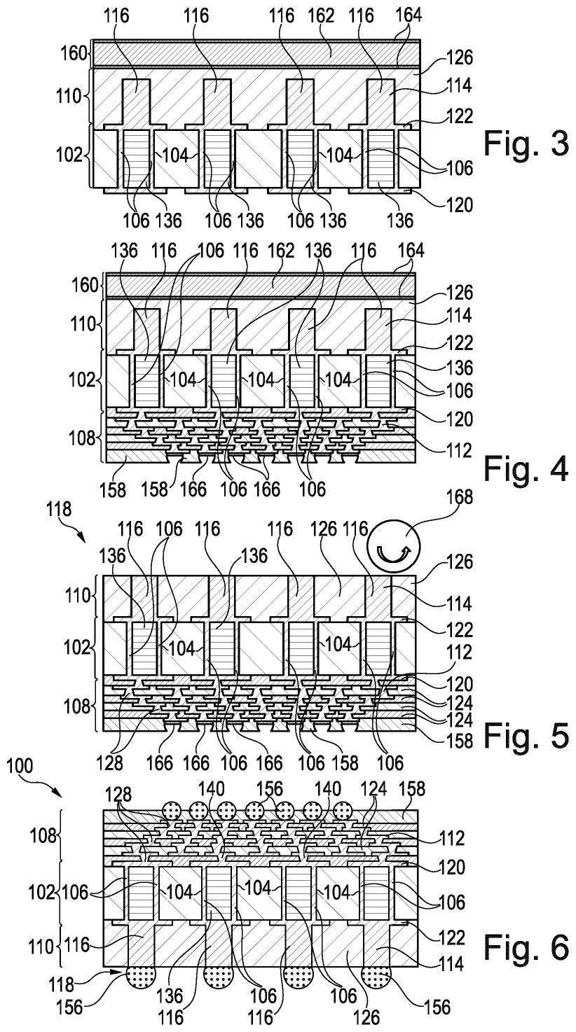

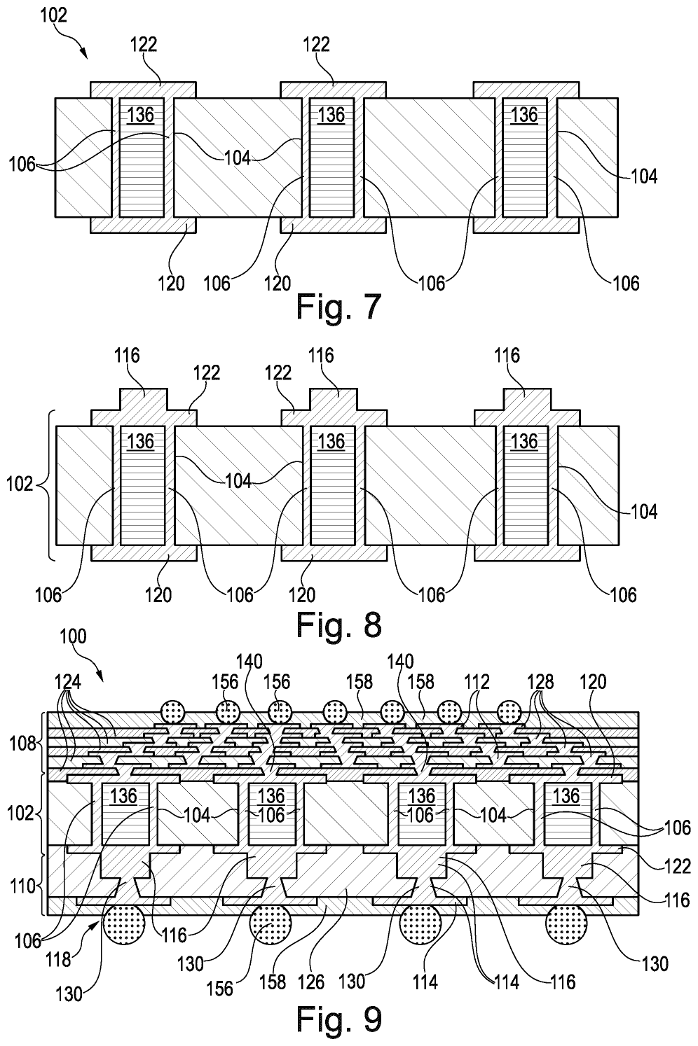

FIG. 3 to FIG. 6 illustrate cross-sectional views of structures obtained during carrying out a method of manufacturing a package 100, shown in FIG. 6, according to an exemplary embodiment of the disclosure.

Referring to FIG. 3, a structure is shown which can be obtained on the basis of a core 102 as described referring to FIG. 1. Core 102 comprises a plurality of parallel vertical through holes 104 each delimited by a wall surface of dielectric core material. Each through hole 104 is coated with a circumferential film of electrically conductive plating material 106, such as plated copper. A remaining hollow volume inside plated through hole 104 may be filled with a filling medium 136, such as an electrically insulating ink or magnetic paste. Electrically conductive planar connection pads 120, 122 close the plated through hole 104 from a top side and a bottom side.

A layer stack 110 is formed on an upper main surface of the core 102. The layer stack 110 comprises a plurality of cylindrical vertical electrically conductive connection elements 116, such as copper pillars with an aspect ratio of at least 0.5 and preferably larger. The cylindrical vertical electrically conductive connection elements 116 are embedded in dielectric material 126, such as epoxy resin (optionally comprising reinforcing particular such as glass fibers). At the bottom side of layer stack 110, the cylindrical vertical electrically conductive connection elements 116 are exposed and directly connected with the electrically conductive planar connection pads 122. Thus, layer stack 110 may be provided with electrically conductive elements 114 including the cylindrical vertical electrically conductive connection elements 116. In the readily manufactured package 100, the cylindrical vertical electrically conductive connection elements 116 may contribute to the provision of an electrically conductive connection interface 118 at a main surface of the layer stack 110 facing away from the core 102.

Moreover, a temporary carrier 160 is attached to an upper main surface of layer stack 110. Temporary carrier 160 may comprise a central dielectric sheet 162 covered by metal foils 164 on both opposing main surfaces thereof. For instance, metal foils 164 may be copper foils. Optionally, a release layer (promoting release of the temporary carrier 160) may be arranged between the central dielectric sheet 162 and the metal foils 164 attached to the layer stack 110 according to FIG. 3. Temporary carrier 160 may be a DCF (Detachable Copper Foil) carrier. Temporary carrier 160 may be laminated on layer stack 110.

Referring to FIG. 4, a further layer stack 108 is formed on an exposed bottom main surface of core 102 according to FIG. 3 for establishing an electrically conductive connection between the electrically conductive planar connection pads 120 and electrically conductive elements 112 of the further layer stack 108. To put it shortly, a further buildup in form of further layer stack 108 is formed on the bottom side of the core 102.

As shown, the further layer stack 108 is provided with a distribution of electrically conductive elements 112 having a higher integration density (i.e., number per volume) than the electrically conductive elements 114 having a lower integration density. The distribution of the electrically conductive elements 112 forms a redistribution structure with a lower pitch on the bottom main surface of the structure shown in FIG. 4 as compared to a larger pitch of layer stack 110 and core 102. Advantageously, the higher manufacturing effort for creating said redistribution structure occurs only in the further layer stack 108, whereas layer stack 110 and core 102 can be manufactured with very low effort and in a simple way.

As shown as well in FIG. 4, a solder resist 158 is formed as a patterned dielectric layer on an exposed surface of layer stack 108. Exposed surface portions of the electrically conductive elements 112 at a bottom of the layer stack 108 may be optionally covered with a surface finish 166, such as ENEPIG, ENIPIG or OSP.

Referring to FIG. 5, the temporary carrier 160 may be removed, for instance by detaching (as indicated schematically by reference sign 168). The upper main surface may then be subjected to copper etching for removing a potentially remaining copper foil or residues thereof. Moreover, exposed material of layer stack 110 may be removed, for instance by grinding, for exposing the cylindrical vertical electrically conductive connection elements 116.

Referring to FIG. 6, the structure obtained according to FIG. 5 is then subjected to backend processing. For instance, electrically conductive connection structures 156, such as solder balls, are applied to exposed metallic surfaces both on top side and on bottom side of the obtained package 100. Thereby, a package 100 according to FIG. 2 can be obtained.

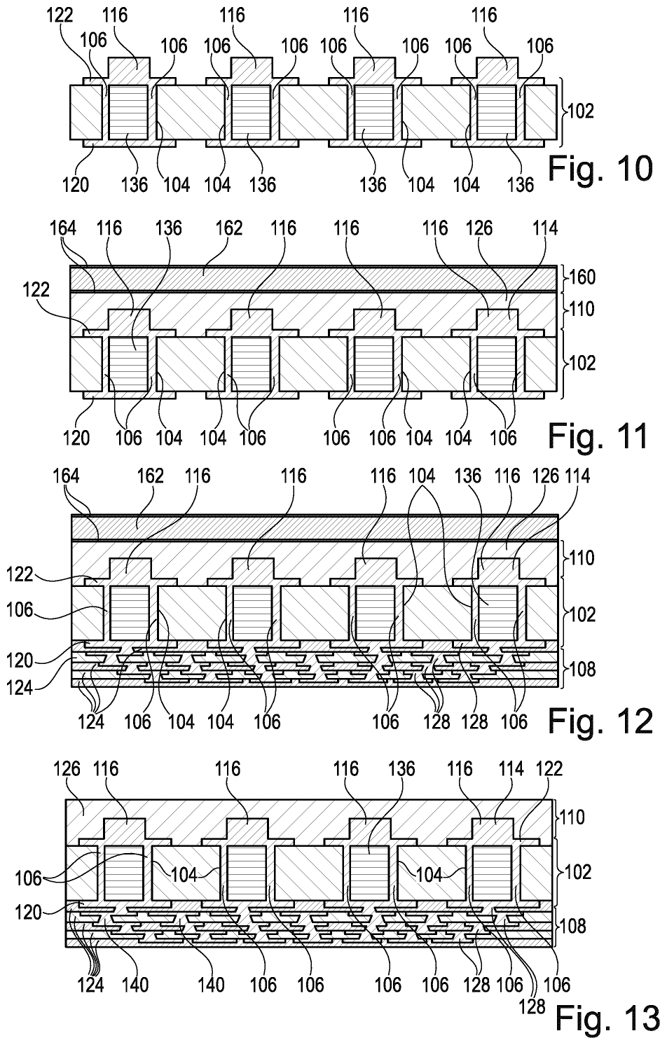

FIG. 7 to FIG. 9 illustrate cross-sectional views of structures obtained during carrying out a method of manufacturing a package 100, shown in FIG. 9, according to an exemplary embodiment of the disclosure.

Referring to FIG. 7, a core 102 can be formed, as described above referring to FIG. 3.

Referring to FIG. 8, cylindrical vertical electrically conductive connection elements 116, here embodied as copper pillars, may be formed on or connected to the further electrically conductive planar connection pads 122 of core 102.

Referring to FIG. 9, a layer stack 110 may be formed by embedding the cylindrical vertical electrically conductive connection elements 116 in dielectric material 126. For instance, this may be accomplished by laminating an at least partially uncured electrically insulating layer structure, for instance a prepreg or resin sheet, onto the cylindrical vertical electrically conductive connection elements 116. Thereby, the cylindrical vertical electrically conductive connection elements 116 are completely covered by the dielectric material 126.

There is also another method for processing the cylindrical vertical electrically conductive connection elements 116. For example, if the resin sheet is polyimide (PI) and/or a photoimageable dielectric (PID), it may be possible to form an opening in the PI/PID material by an exposure process. The cylindrical vertical electrically conductive connection elements 116 can then be formed by galvanic plating. For exposing the cylindrical vertical electrically conductive connection elements 116, an exposure process can be applied.

The embedded cylindrical vertical electrically conductive connection elements 116 may then be accessed and exposed by laser drilling dielectric material 126 for exposing horizontal flange faces of the cylindrical vertical electrically conductive connection elements 116. By copper plating, the laser drilled vias may be filled. As a result, the further vertical electrically conductive connection elements 130 are obtained which are electrically connected to the flange faces of the cylindrical vertical electrically conductive connection elements 116. A wide bottom of the conical further vertical electrically conductive connection elements 130 may be connected with a pad-type further electrically conductive element 114 to complete formation of the electrically conductive connection interface 118.

On the opposing other main surface of core 102, layer stack 108 may be formed, as described above referring to FIG. 6.

The manufacturing process may be completed by forming solder resist 158 and electrically conductive connection structures 156 on both opposing surfaces of package 100 according to FIG. 9. Said package 100 corresponds to FIG. 1.

By the described manufacturing process, package 100 may be obtained which is configured as asymmetric chip-last fan-out substrate since the layer count on both sides is different. Hence, package 100 has an asymmetric buildup on both opposing main surfaces of core 102. However, due to the design of the dielectric material 124, 126 in terms of CTE and Young modulus as well as by the provision of constant amounts of dielectric material 124, 126 in both layer stacks 108, 110, proper warpage control may be achieved regardless of the asymmetric buildup. Moreover, one or more electronic components 132 (see FIG. 17) may be mounted at the very end of the manufacturing process. Such a chip-last manufacture may increase the yield. Furthermore, the redistribution structure 128 in layer stack 108 provides a fan-out function. Also, the thick core 102 contributes to a reliable avoidance of excessive warpage. The metallic structures in package 100 (i.e., the metallization of metallized through hole core 102, the metal pillars in layer stack 110, and the fine redistribution layer in layer stack 108 as well as the BGA-type interface 118) ensure a high electric reliability. The DCF process provides for an improved productivity.

FIG. 10 to FIG. 15 illustrate cross-sectional views of structures obtained during carrying out a method of manufacturing a package 100, shown in FIG. 15, according to an exemplary embodiment of the disclosure.

Referring to FIG. 10, a structure is shown which can be obtained as described above referring to FIG. 8. Said structure comprises a thick metallized through hole core 102 with copper pillars as cylindrical vertical electrically conductive connection elements 116.

Referring to FIG. 11, a temporary carrier 160 may be attached, as explained referring to FIG. 3. Descriptively speaking, a DCF substrate may be laminated on the structure shown in FIG. 10 after embedding the cylindrical vertical electrically conductive connection elements 116 in dielectric material 126.

Referring to FIG. 12, a further buildup may be formed on the bottom surface of core 102 to thereby create layer stack 108 (see description of FIG. 4).

Referring to FIG. 13, the temporary carrier 160 is detached, followed by copper etching, as described above referring to FIG. 5.

Referring to FIG. 14, electrically conductive connection elements 130 are formed, as copper-filled laser vias, in dielectric material 126 for connecting electrically with the cylindrical vertical electrically conductive connection elements 116 (see description of FIG. 9). Patterned metal layers may then be formed on both opposing exposed main surfaces of layer stacks 108, 110.

Referring to FIG. 15, a backend process may be carried out for forming solder resist 158 and electrically conductive connection structures 156, as described referring to FIG. 9.

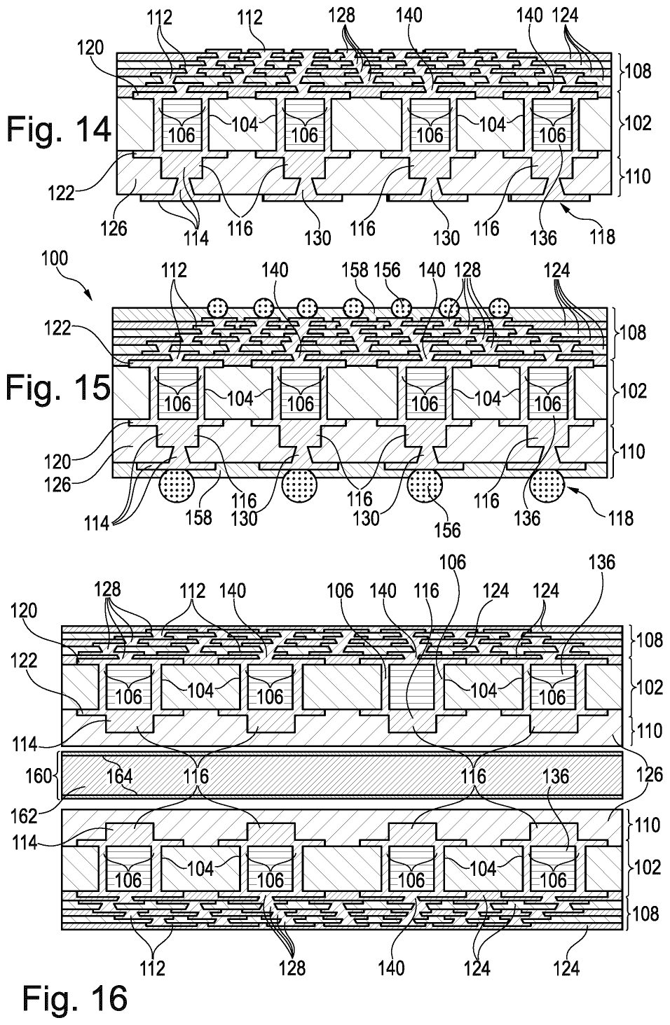

FIG. 16 to FIG. 18 illustrate cross-sectional views of structures obtained during carrying out a method of manufacturing a package 100, shown in FIG. 18, according to an exemplary embodiment of the disclosure.

Referring to FIG. 16, a respective package 100 may be manufactured on each of both opposing main surfaces of temporary carrier 160. After having created the buildup shown in FIG. 16, pre-forms of packages 100 may be detached from both opposing main surfaces of the temporary carrier 160. For example, this may be simplified by a respective release layer of temporary carrier 160 arranged between the central dielectric sheet 162 and each respective metal foil 164.

By the double-sided processing of packages 100 on both opposing main surfaces of the temporary carrier 160 according to FIG. 16, a better productivity may be obtained and the capacity or manufacturing efficiency will be double increased as well. In this context, it may be particularly advantageous to use, as temporary carrier 160, the above described DCF substrate and a corresponding process.

Referring to FIG. 17, further processing of a package 100 will be described. A starting point of the further processing according to FIG. 17 may be a package 100 according to FIG. 1, FIG. 9, FIG. 15, or obtained from the processing according to FIG. 16. Although not shown, also the embodiment of FIG. 2 may be used as a starting point for the further processing according to FIG. 17 and FIG. 18.

As shown in FIG. 17, electronic components 132 are surface mounted on the first layer stack 108. For instance, the electronic components 132 may be semiconductor chips. For assembly of the electronic components 132 on package 100, pads 170 of the electronic components 132 may be electrically coupled with the exposed electrically conductive elements 112 of the first layer stack 108 by the electrically conductive connection structure 156. Although the electrically conductive connection structure 156 may be solder balls for creating a solder connection, the electrically conductive connection structure 156 may be alternatively a sinter structure, electrically conductive glue or a metallic bonding structure.

For the purpose of reliably electrically insulating an interface between layer stack 108 and electronic components 132 and for improving mechanical reliability, an electrically insulating underfill 172 may be applied to said interface.

By the described chip-last packaging manufacturing architecture, fan-out packages 100 may be manufactured with high yield.

Referring to FIG. 18, the surface mounted components 132 may be encapsulated by a mold compound 174. Furthermore, the second layer stack 110 may be mounted on a mounting base 134, such as a printed circuit board (PCB).

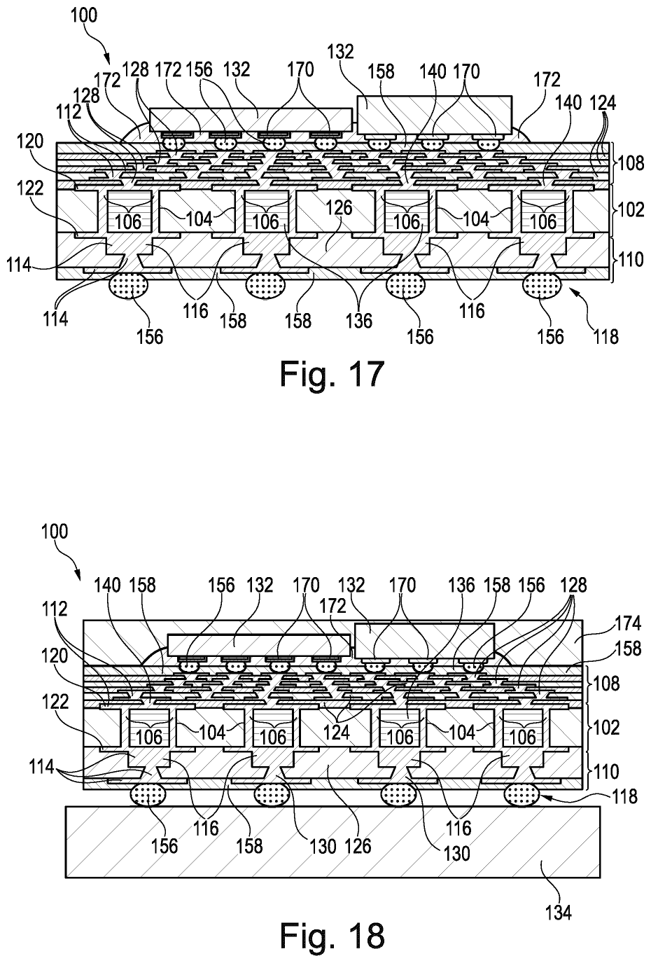

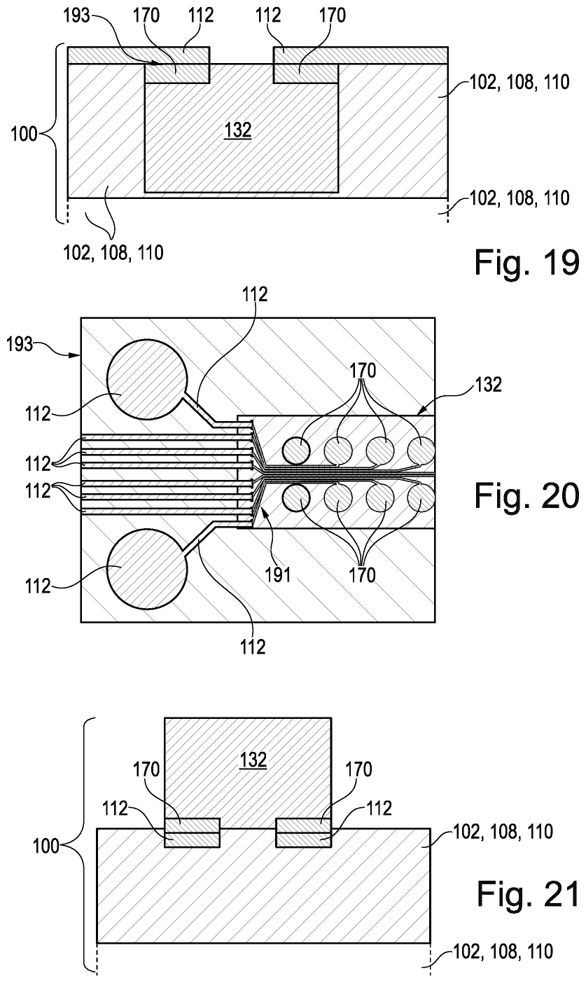

FIG. 19 illustrates a cross-sectional view of a package 100 according to another exemplary embodiment of the disclosure. FIG. 20 illustrates a horizontal connection plane 193 of the package 100 according to FIG. 19.

The package 100 according to FIG. 19 and FIG. 20 can be embodied for instance in a way as described above referring to FIG. 1 to FIG. 18, and may comprise in particular a core 102 and stacks 108, 110. In the following, only the differences between the embodiment of FIG. 19 and FIG. 20 and the previously described embodiments will be mentioned.

According to FIG. 19, an electronic component 132 is embedded in package 100 in a way that pads 170 of the electronic component 132 are electrically coupled with electrically conductive elements 112 of the package 100 at an exterior surface of the package 100. As shown in FIG. 20, the connection between the pads 170 and the electrically conductive elements 112 are all established within horizontal connection plane 193. Again referring to FIG. 20, the electronic component 132 has a planar redistribution layer 191 at a main surface thereof, in particular in the chip plane.

The configuration according to FIG. 19 and FIG. 20 does not only allow a substantially vertical signal propagation, but also a horizontal signal propagation within the horizontal connection plane 193. In this embodiment, the electronic component 132 is embedded in the stack configuration of the package 100 and has a common level interconnection with the stacked configuration below. For example, the electronic component 132 may be embedded in the stack 108 and/or in the core 102. After finishing encapsulation, the whole surface may be ground to expose the pad 170 of the electronic component 132. Thereafter, it may be possible to sputter a seed layer on the whole surface and to pattern it with a lithographic process. Thereafter, a plating process may be executed for thickening the patterned metallic surface layer. An etching process may follow. An electrical connection may be formed between the pad 170 of the electronic component 132 and the component carrier-type stacked configuration at the same level.

FIG. 21 illustrates a cross-sectional view of a package 100 according to still another exemplary embodiment of the disclosure.

The package 100 according to FIG. 21 can be embodied for instance in a way as described above referring to FIG. 1 to FIG. 20, and may comprise in particular a core 102 and stacks 108, 110. In the following, only the differences between the embodiment of FIG. 21 and the previously described embodiments will be mentioned.

According to FIG. 21, electronic component 132 is surface mounted on the stacked configuration of core 102 and stacks 108, 110 so that bottom-sided pads 170 of the electronic component 102 are directly physically connected face-to-face with electrically conductive elements 112 at a top surface of the stacked configuration. At the same time, a dielectric surface portion of the electronic component 132 and of the stacked configuration can also be directly physically connected face-to-face. This connection can be established, for example, by hybrid bonding.

Still referring to FIG. 21, the electronic component 132 may be mounted on the surface of the stacked configuration. In this context, it may also be possible to create a metal-to-metal connection between the electrically conductive elements 112 on the surface of the stacked configuration and the pads 170 of the surface mounted electronic component 132. In a corresponding manufacturing process, it may be possible to grind metallic material on the surfaces of both the electronic component 132 and the component carrier-type stacked configuration to expose metallic connection material externally. Exposed metal at both connection surfaces may then be treated for establishing a direct metal to metal bonding (for instance by hybrid bonding). Descriptively speaking, the metallic material on both connection surfaces may be merged with each other between the electronic component 132 and the stacked configuration.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A package, which comprises:
a core having at least one through hole delimited by a wall surface which is at least partially covered with at least one electrically conductive plating material;
a first layer stack on one main surface of the core; and
a second layer stack on an opposing other main surface of the core;
wherein the first layer stack has electrically conductive elements with a higher integration density than further electrically conductive elements with a lower integration density of the second layer stack; and
wherein the further electrically conductive elements comprise at least one cylindrical vertical electrically conductive connection element contributing to the formation of an electrically conductive connection interface at a main surface of the second layer stack facing away from the core.

2. The package according to claim 1, wherein at least part of the electrically conductive elements is electrically coupled with the at least one plating material.

3. The package according to claim 1, wherein at least part of the further electrically conductive elements is electrically coupled with the at least one plating material.

4. The package according to any of claims 1, comprising at least one of the following features:
at least one electrically conductive planar connection pad at least partially covering a respective one of the at least one through hole at one of the one main surface and the other main surface of the core and being electrically connected with a respective one of the at least one plating material;
comprising at least one further electrically conductive planar connection pad at least partially covering a respective one of the at least one through hole at the other one of the one main surface and the other main surface of the core and being electrically connected with a respective one of the at least one plating material;
wherein at least one of the at least one electrically conductive planar connection pad and the at least one further electrically conductive planar connection pad extends circumferentially beyond the respective one of the at least one plating material;
wherein vertical through connections of the electrically conductive elements are directly electrically connected with one of the at least one electrically conductive planar connection pad and the at least one further electrically conductive planar connection pad;
wherein the at least one cylindrical vertical electrically conductive connection element is directly electrically connected with one of the at least one electrically conductive planar connection pad and the at least one further electrically conductive planar connection pad.

5-8. (canceled)

9. The package according to claims 1, wherein dielectric material of the first layer stack has a lower coefficient of thermal expansion than dielectric material of the second layer stack.

10. The package according to claims 1, wherein an amount of dielectric material of the first layer stack is substantially the same as an amount of dielectric material of the second layer stack.

11. The package according to claims 1, wherein dielectric material of the first layer stack comprises er consists of a high Young modulus material.

12. The package according to claims 1, wherein dielectric material of the second layer stack comprises a low Young modulus material.

13. The package according to claims 1, wherein a respective one of the at least one plating material is electrically connected to and axially displaced with respect to an assigned one of the at least one cylindrical vertical electrically conductive connection element.

14. The package according to claims 1, wherein an integration density of the core with its at least one plating material is substantially the same as the integration density of the further electrically conductive elements of the second layer stack.

15. The package according to claims 1, further comprising at least one of the following features:
wherein a ratio between a height and a diameter of the at least one cylindrical vertical electrically conductive connection element is at least 0.5;
wherein a vertical thickness of the core is at least 500 μm;
wherein the first layer stack comprises a redistribution structure;
wherein the electrically conductive connection interface provides a grid array interface. 16-18. (canceled)

19. The package according to claims 1, wherein the at least one cylindrical vertical electrically conductive connection element is vertically spaced with respect to the electrically conductive connection interface by at least one further vertical electrically conductive connection element,
wherein the at least one further vertical electrically conductive connection element comprises at least one metal-filled via tapering in a direction away from the electrically conductive connection interface.

20. (canceled)

21. The package according to claims 1, wherein the at least one cylindrical vertical electrically conductive connection element extends up to the electrically conductive connection interface.

22. The package according to claims 1, comprising at least one component surface mounted on the first layer stack.

23. The package according to claims 1, comprising a mounting base on which the second layer stack is mounted.

24. The package according to claims 1, comprising a dielectric filling medium at least partially filling the at least one through hole between different sections of the plating material.

25. The package according to claims 1, comprising at least one of the following features:
wherein the at least one cylindrical vertical electrically conductive connection element comprises at least one metal pillar;
wherein the core comprises at least one of an organic material, glass, a ceramic, and a semiconductor.

26. (canceled)

27. The package according to any of claim 1, wherein the core has at least two through holes extending parallel to each other and each being delimited by a respective wall surface which is at least partially covered with a respective electrically conductive plating material.

28. The package according to any of claims 1, wherein the further electrically conductive elements comprise at least two cylindrical vertical electrically conductive connection elements extending parallel to each other and each contributing to the formation of the electrically conductive connection interface.

29. A method of manufacturing a package, wherein the method comprises:
providing a core having at least one through hole delimited by a wall surface which is at least partially covered with at least one electrically conductive plating material;
forming a first layer stack on one main surface of the core;
forming a second layer stack on an opposing other main surface of the core, wherein the first layer stack has electrically conductive elements with a higher integration density than further electrically conductive elements with a lower integration density of the second layer stack; and
providing the further electrically conductive elements with at least one cylindrical vertical electrically conductive connection element for contributing to the formation of an electrically conductive connection interface at a main surface of the second layer stack facing away from the core.
